(19) United States
(12) Patent Application Publication
(10) Pub. No.: US 2025/0374639 A1
(43) Pub. Date: Dec. 4, 2025

(54) SEMICONDUCTOR STRUCTURE

(71) Applicant: Powerchip Semiconductor Manufacturing Corporation, Hsinchu (TW)

(72) Inventor: Wen-Yueh Chang, Hsinchu City (TW)

(73) Assignee: Powerchip Semiconductor Manufacturing Corporation, Hsinchu (TW)

(21) Appl. No.: 18/766,685

(22) Filed: Jul. 9, 2024

(30) Foreign Application Priority Data
Jun. 4, 2024 (TW) 113120653

(51) Int. Cl. H01L 29/423; H01L 29/49

(52) U.S. Cl. CPC H10D 64/513; H10D 64/518; H10D 64/667

(57) ABSTRACT

Disclosed is a semiconductor structure including a substrate, a first conductive layer, a second conductive layer, a work function layer, a filling layer, and a first dielectric layer. The first conductive layer is located in the substrate. The second conductive layer is located between the first conductive layer and the substrate. The work function layer is located on the first conductive layer. A cross-sectional shape of the work function layer is U-shaped and has a recess. The filling layer is located in the recess. A top surface of the filling layer is higher than a top surface of the work function layer. The first dielectric layer is located between the second conductive layer and the substrate and between the work function layer and the substrate.

### CROSS-REFERENCE TO RELATED APPLICATION

This application claims the priority benefit of Taiwan application serial no. 113120653, filed on Jun. 4, 2024. The entirety of the above-mentioned patent application is hereby incorporated by reference herein and made a part of this specification.

### BACKGROUND

### Technical Field

The disclosure relates to a semiconductor structure, and in particular to a semiconductor structure having a recessed gate.

### Description of Related Art

Currently, a semiconductor structure with a recessed gate (or a buried gate) has been developed. However, how to improve the reliability and electrical performance of the semiconductor structure is the goal of continuous efforts.

### SUMMARY

The disclosure provides a semiconductor structure, which may have higher reliability and better electrical performance.

The disclosure provides a semiconductor structure, including a substrate, a first conductive layer, a second conductive layer, a work function layer, a filling layer, and a first dielectric layer. The first conductive layer is located in the substrate. The second conductive layer is located between the first conductive layer and the substrate. The work function layer is located on the first conductive layer. A cross-sectional shape of the work function layer is U-shaped and has a recess. The filling layer is in the recess. A top surface of the filling layer is higher than a top surface of the work function layer. The first dielectric layer is located between the second conductive layer and the substrate and between the work function layer and the substrate.

According to an embodiment of the disclosure, in the semiconductor structure, a material of the first conductive layer is, for example, tungsten.

According to an embodiment of the disclosure, in the semiconductor structure, a top surface of the first conductive layer and a top surface of the second conductive layer may be of the same height.

According to an embodiment of the disclosure, in the semiconductor structure, the top surface of the first conductive layer may be lower than the top surface of the second conductive layer.

According to an embodiment of the disclosure, in the semiconductor structure, the second conductive layer may be further located between the work function layer and the first dielectric layer.

According to an embodiment of the disclosure, in the semiconductor structure, the top surface of the second conductive layer and the top surface of the work function layer may be of the same height.

According to an embodiment of the disclosure, in the semiconductor structure, a material of the second conductive layer is, for example, titanium nitride (TiN).

According to an embodiment of the disclosure, in the semiconductor structure, a material of the work function layer may be a low work function material or an active material.

According to an embodiment of the disclosure, in the semiconductor structure, the low work function material is, for example, silicon.

According to an embodiment of the disclosure, in the semiconductor structure, the active material is, for example, titanium.

According to an embodiment of the disclosure, in the semiconductor structure, the top surface of the filling layer and a top surface of the substrate may be of the same height.

According to an embodiment of the disclosure, in the semiconductor structure, the top surface of the filling layer may be lower than the top surface of the substrate.

According to an embodiment of the disclosure, the semiconductor structure may further include a second dielectric layer. The second dielectric layer is located on the top surface of the filling layer, the top surface of the work function layer, and the top surface of the second conductive layer.

According to an embodiment of the disclosure, in the semiconductor structure, the first dielectric layer may be located between the second dielectric layer and the substrate.

According to an embodiment of the disclosure, in the semiconductor structure, the top surface of the filling layer may be higher than the top surface of the second conductive layer.

According to an embodiment of the disclosure, in the semiconductor structure, a material of the filling layer may be a dielectric material or a conductive material.

According to an embodiment of the disclosure, the semiconductor structure may further include a first doped region and a second doped region. The first doped region and the second doped region are located in the substrate on both sides of the filling layer.

According to an embodiment of the disclosure, in the semiconductor structure, the top surface of the work function layer may be higher than a bottom surface of the first doped region and a bottom surface of the second doped region.

According to an embodiment of the disclosure, in the semiconductor structure, the top surface of the second conductive layer may be lower than or higher than the bottom surface of the first doped region and the bottom surface of the second doped region.

According to an embodiment of the disclosure, in the semiconductor structure, the top surface of the filling layer may be higher than the bottom surface of the first doped region and the bottom surface of the second doped region.

Based on the above, in the semiconductor structure provided by the disclosure, the first conductive layer is located in the substrate. The second conductive layer is located between the first conductive layer and the substrate. The work function layer is located on the first conductive layer. The cross-sectional shape of the work function layer is U-shaped and has the recess. The filling layer is in the recess. The top surface of the filling layer is higher than the top surface of the work function layer. The first dielectric layer is located between the second conductive layer and the substrate and between the work function layer and the substrate. Since the first conductive layer, the second conductive layer, and the work function layer may be configured as a gate of a recessed transistor, a resistance of the recessed gate may be reduced, thereby allowing the semiconductor structure to have better electrical performance.

In order to make the features and advantages of the disclosure more comprehensible, the following examples are given and described in detail with the accompanying drawings as follows.

### BRIEF DESCRIPTION OF THE DRAWINGS

FIG. 1 is a cross-sectional view of a semiconductor structure according to some embodiments of the disclosure.

FIG. 2 is a cross-sectional view of a semiconductor structure according to other embodiments of the disclosure.

FIG. 3 is a cross-sectional view of a semiconductor structure according to other embodiments of the disclosure.

### DETAILED DESCRIPTION OF DISCLOSED EMBODIMENTS

The embodiments are described in detail below with reference to the accompanying drawings, but the embodiments are not intended to limit the scope of the disclosure. For ease of understanding, the same components in the following description are denoted by the same reference symbols. In addition, the drawings are for illustrative purposes only and are not drawn to the original dimensions. In fact, the dimensions of the various features may be arbitrarily increased or reduced for clarity of discussion.

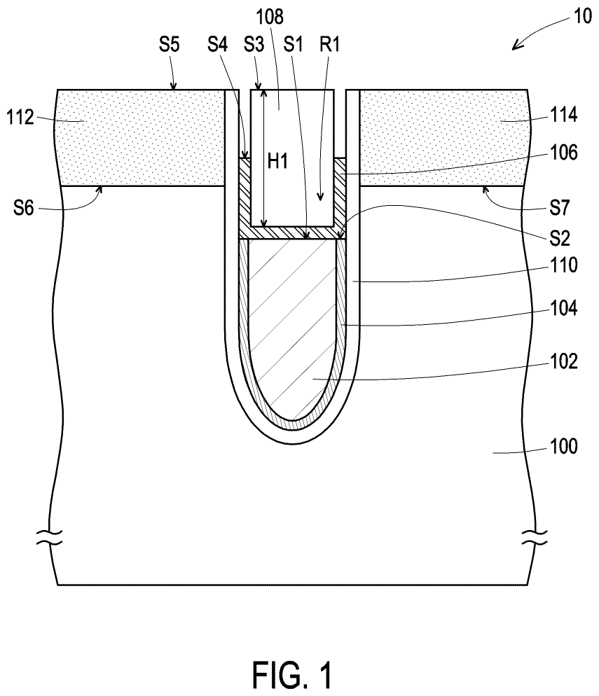

FIG. 1 is a cross-sectional view of a semiconductor structure according to some embodiments of the disclosure.

Please refer to FIG. 1. A semiconductor structure 10 includes a substrate 100, a conductive layer 102, a conductive layer 104, a work function layer 106, a filling layer 108, and a dielectric layer 110. In some embodiments, the semiconductor structure 10 may be a transistor with a recessed gate (or a buried gate), and may be applied to dynamic random access memory (DRAM). In some embodiments, the substrate 100 may be a semiconductor substrate, such as a silicon substrate.

The conductive layer 102 is located in the substrate 100. In some embodiments, a material of the conductive layer 102 is, for example, tungsten. The conductive layer 104 is located between the conductive layer 102 and the substrate 100. In some embodiments, a top surface S1 of the conductive layer 102 and a top surface S2 of the conductive layer 104 may have the same height. In some embodiments, a material of the conductive layer 104 is, for example, titanium nitride.

The work function layer 106 is located on the conductive layer 102. The work function layer 106 may further be located on the conductive layer 104. A cross-sectional shape of the work function layer 106 is U-shaped and has a recess R1. In the embodiment, a material of the work function layer 106 may be a low work function material. In some embodiments, the low work function material is, for example, silicon.

The filling layer 108 is located in the recess R1. A top surface S3 of the filling layer 108 is higher than a top surface S4 of the work function layer 106. In the embodiment, the top surface S3 of the filling layer 108 and a top surface S5 of the substrate 100 may be of the same height, but the disclosure is not limited thereto. In other embodiments, the top surface S3 of the filling layer 108 may be lower than the top surface S5 of the substrate 100. In some embodiments, the top surface S3 of the filling layer 108 may be higher than the top surface S2 of the conductive layer 104. In some embodiments, the top surface S4 of the work function layer 106 may be higher than half of an overall height H1 of the filling layer 108. In the embodiment, a material of the filling layer 108 may be a dielectric material. In some embodiments, the material of the filling layer 108 is, for example, silicon dioxide.

The dielectric layer 110 is located between the conductive layer 104 and the substrate 100 and between the work function layer 106 and the substrate 100. The dielectric layer 110 may be configured as a gate dielectric layer. In some embodiments, a material of the dielectric layer 110 is, for example, silicon dioxide.

The semiconductor structure 10 may further include a doped region 112 and a doped region 114. The doped region 112 and the doped region 114 are located in the substrate 100 on both sides of the filling layer 108. In some embodiments, the top surface S4 of the work function layer 106 may be higher than a bottom surface S6 of the doped region 112 and a bottom surface S7 of the doped region 114. In the embodiment, the top surface S2 of the conductive layer 104 may be lower than the bottom surface S6 of the doped region 112 and the bottom surface S7 of the doped region 114. In some embodiments, the top surface S3 of the filling layer 108 may be higher than the bottom surface S6 of the doped region 112 and the bottom surface S7 of the doped region 114.

Based on the above embodiment, in the semiconductor structure 10, the conductive layer 102 is located in the substrate 100. The conductive layer 104 is located between the conductive layer 102 and the substrate 100. The work function layer 106 is located on the conductive layer 102. The cross-sectional shape of the work function layer 106 is U-shaped and has the recess R1. The filling layer 108 is located in the recess R1. The top surface S3 of the filling layer 108 is higher than the top surface S4 of the work function layer 106. The dielectric layer 110 is located between the conductive layer 104 and the substrate 100 and between the work function layer 106 and the substrate 100. Since the conductive layer 102, the conductive layer 104, and the work function layer 106 may be configured as a gate of a recessed transistor, a resistance of the recessed gate may be reduced, thereby allowing the semiconductor structure 10 to have better electrical performance.

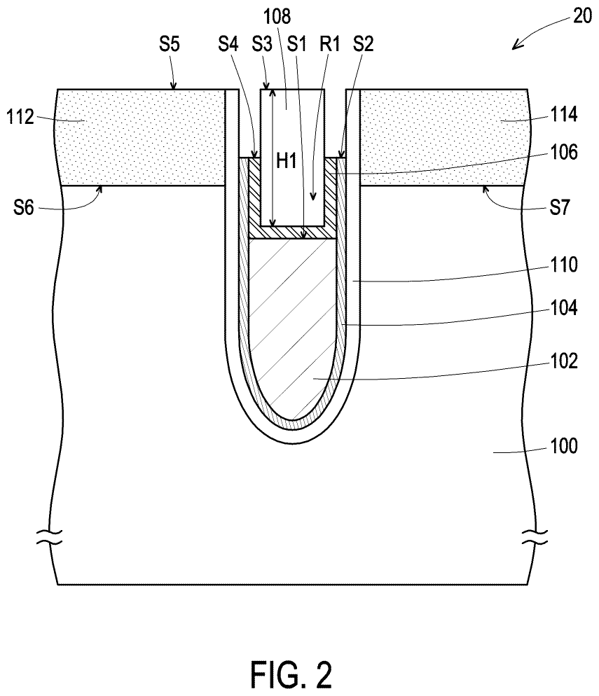

FIG. 2 is a cross-sectional view of a semiconductor structure according to other embodiments of the disclosure.

Please refer to FIG. 1 and FIG. 2. Differences between a semiconductor structure 20 of FIG. 2 and the semiconductor structure 10 of FIG. 1 are as follows. In the semiconductor structure 20, a top surface S1 of a conductive layer 102 may be lower than a top surface S2 of a conductive layer 104. In the semiconductor structure 20, the conductive layer 104 may be further located between a work function layer 106 and a dielectric layer 110. In the semiconductor structure 20, a material of the work function layer 106 may be an active material. In a condition where the material of the work function layer 106 is the active material, the work function layer 106 (the active material) may react with the conductive layer 104 through a thermal process and reduce a work function of an upper part of the conductive layer 104. In some embodiments, the active material is, for example, titanium. In the semiconductor structure 20, a top surface S2 of the conductive layer 104 may be higher than a bottom surface S6 of a doped region 112 and a bottom surface S7 of a doped region 114. In the semiconductor structure 20, the top surface S2 of the conductive layer 104 and a top surface S4 of the work function layer 106 may be of the same height. In addition, in FIG. 1 and FIG. 2, the same or similar components are represented by the same reference symbols, and descriptions thereof are omitted.

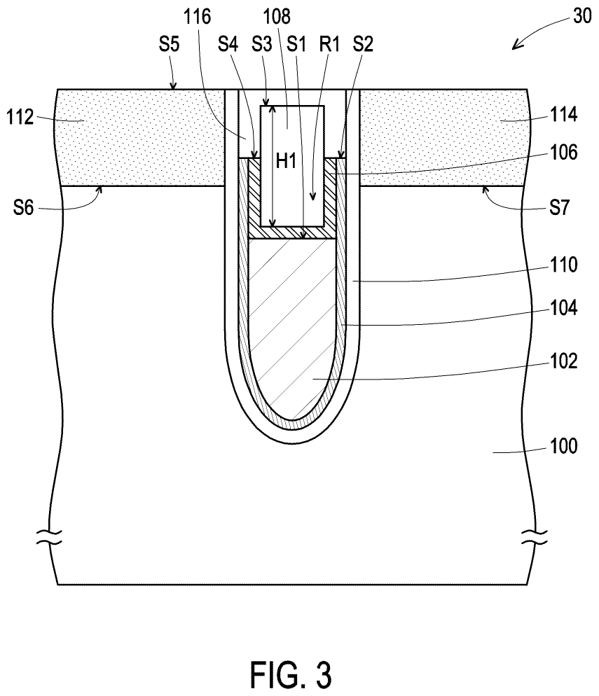

FIG. 3 is a cross-sectional view of a semiconductor structure according to other embodiments of the disclosure.

Please refer to FIG. 2 and FIG. 3. Differences between a semiconductor structure 30 of FIG. 3 and the semiconductor structure 20 of FIG. 2 are as follows. A material of a filling layer 108 in the semiconductor structure 20 may be a dielectric material, and a material of a filling layer 108 in the semiconductor structure 30 may be a conductive material. In this way, in the semiconductor structure 30, a conductive layer 102, a conductive layer 104, a work function layer 106, and the filling layer 108 may be configured as a gate of a recessed transistor, thereby further reducing a resistance of the recessed gate. In the semiconductor structure 30, a top surface S3 of the filling layer 108 may be lower than a top surface S5 of a substrate 100. In addition, the semiconductor structure 30 may further include a dielectric layer 116. The dielectric layer 116 is located on the top surface S3 of the filling layer 108, a top surface S4 of the work function layer 106, and a top surface S2 of the conductive layer 104. The dielectric layer 110 may be located between the dielectric layer 116 and the substrate 100. In some embodiments, a material of the dielectric layer 116 is, for example, silicon dioxide. In addition, in FIG. 2 and FIG. 3, the same or similar components are represented by the same reference symbols, and descriptions thereof are omitted.

In summary, the semiconductor structure of the embodiment includes the substrate, the first conductive layer, the second conductive layer, the work function layer, the filling layer, and the first dielectric layer. The first conductive layer is located in the substrate. The second conductive layer is located between the first conductive layer and the substrate. The work function layer is located on the first conductive layer. The cross-sectional shape of the work function layer is U-shaped and has the recess. The filling layer is in the recess. The top surface of the filling layer is higher than the top surface of the work function layer. The first dielectric layer is located between the second conductive layer and the substrate and between the work function layer and the substrate. Since the first conductive layer, the second conductive layer, and the work function layer may be configured as the gate of the recessed transistor, the resistance of the recessed gate may be reduced, thereby allowing the semiconductor structure to have better electrical performance.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor structure, comprising:
a substrate;
a first conductive layer, located in the substrate;
a second conductive layer, located between the first conductive layer and the substrate;
a work function layer, located on the first conductive layer, wherein a cross-sectional shape of the work function layer is U-shaped and has a recess;
a filling layer, located in the recess, wherein a top surface of the filling layer is higher than a top surface of the work function layer; and
a first dielectric layer, located between the second conductive layer and the substrate and between the work function layer and the substrate.

2. The semiconductor structure according to claim 1, wherein a material of the first conductive layer comprises tungsten.

3. The semiconductor structure according to claim 1, wherein a top surface of the first conductive layer and a top surface of the second conductive layer are of the same height.

4. The semiconductor structure according to claim 1, wherein a top surface of the first conductive layer is lower than a top surface of the second conductive layer.

5. The semiconductor structure according to claim 1, wherein the second conductive layer is further located between the work function layer and the first dielectric layer.

6. The semiconductor structure according to claim 1, wherein a top surface of the second conductive layer and the top surface of the work function layer are of the same height.

7. The semiconductor structure according to claim 1, wherein a material of the second conductive layer comprises titanium nitride.

8. The semiconductor structure according to claim 1, wherein a material of the work function layer comprises a low work function material or an active material.

9. The semiconductor structure according to claim 8, wherein the low work function material comprises silicon.

10. The semiconductor structure according to claim 8, wherein the active material comprises titanium.

11. The semiconductor structure according to claim 1, wherein the top surface of the filling layer and a top surface of the substrate are of the same height.

12. The semiconductor structure according to claim 1, wherein the top surface of the filling layer is lower than a top surface of the substrate.

13. The semiconductor structure according to claim 12, further comprising:
a second dielectric layer, located on the top surface of the filling layer, the top surface of the work function layer, and a top surface of the second conductive layer.

14. The semiconductor structure according to claim 13, wherein the first dielectric layer is located between the second dielectric layer and the substrate.

15. The semiconductor structure according to claim 1, wherein the top surface of the filling layer is higher than a top surface of the second conductive layer.

16. The semiconductor structure according to claim 1, wherein a material of the filling layer comprises a dielectric material or a conductive material.

17. The semiconductor structure according to claim 1, further comprising:
a first doped region and a second doped region, located in the substrate on both sides of the filling layer.

18. The semiconductor structure according to claim 17, wherein the top surface of the work function layer is higher than a bottom surface of the first doped region and a bottom surface of the second doped region.

19. The semiconductor structure according to claim 17, wherein a top surface of the second conductive layer is lower than or higher than a bottom surface of the first doped region and a bottom surface of the second doped region.

20. The semiconductor structure according to claim 17, wherein the top surface of the filling layer is higher than a bottom surface of the first doped region and a bottom surface of the second doped region.
